(19) United States
(12) Patent Application Publication
(10) Pub. No.: US 2016/0077171 A1
(43) Pub. Date: Mar. 17, 2016

(54) NMR EXTRACTABLE PROBE CASSETTE MEANS AND METHODS THEREOF

(71) Applicant: ASPECT AL LTD., Netanya (IL)

(72) Inventors: Itzchak RABINOVITZ, Ness Tsiona (IL); Tal COHEN, Herzliya (IL)

(21) Appl. No.: 14/504,907

(22) Filed: Oct. 2, 2014

Related U.S. Application Data
(60) Provisional application No. 62/050,221, filed on Sep. 15, 2014.

(51) Int. Cl. G01R 33/34; G01R 3/00; G01R 33/48; G01R 33/00

(52) U.S. Cl. CPC G01R 33/34; G01R 33/0052; G01R 3/00; G01R 33/48

(57) ABSTRACT

An extractable nuclear magnetic resonance (NMR) probe cassette for reversibly positioning a probe in an NMR device. The probe cassette includes: a body having a longitudinal axis having and an opening centered on the axis at one end; a conduit extending through the central opening in the body, for containing a sample; and an RF coil that spirals about at least a portion of the central opening. The probe cassette also includes at least one longitudinal guide along its body's longitudinal axis for reversibly and reproducibly guiding the probe cassette in and out of an NMR device.

### FIELD OF THE INVENTION

The present invention generally relates to nuclear magnetic resonance (NMR) testing apparatus and in particular to extractable probe cassettes for NMR device, means and methods thereof.

### BACKGROUND OF THE INVENTION

Nuclear magnetic resonance (NMR) testing of substances to determine the constituents therein is well known in the art. In known devices, the sample can be arranged between the poles of a magnet and enclosed by a wire coil to enable a sample to be subjected to RF electromagnetic pulses of a predetermined frequency. The resulting NMR pulse generated by the nuclei of the sample under test can be detected and processed by the NMR device in a well-known manner to identify the sample constituents.

NMR analysis can be performed in devices commonly known as spectrometers. These spectrometers are designed so as to have a probe, accepting the sample to be analyzed, between poles of a magnet. The RF coils and tuning circuitry associated with the probe create a field (B) that rotates the net magnetization of the nucleus. These RF coils also detect the transverse magnetization as it passes across the X, Y plane. The RF coil pulses the sample nucleus at the Lamor frequency, so as to generate a readable signal for sample identification.

An exemplary probe that performs in accordance with that described immediately above is disclosed in commonly owned U.S. Pat. No. 5,371,464 (Rapoport), and is incorporated herein as a reference. This probe and others like it, while an improvement in the art, still have several disadvantages.

A problem with current configurations of probe systems is their built-in assembly. NMR probes are provided as an inherent feature of the NMR device and are manufactured intrinsically in the device. As such, any defect, breakage or contamination of the probes involves the disassembly of the entire NMR device and requires expensive and elaborate repair. In addition, the probe comprises a conduit for inserting a sample. A smaller or larger diameter of the sampling conduit may be desired and such customization is rather limited in the probes available today. A customized opening will enable a more accurate positioning of the RF coils, and a larger signal-to-noise analysis. Another disadvantage of currently available built-in probes is the difficulty of cleaning such a probe that is part of the NMR apparatus.

Thus, there is a long-felt need for a probe that is comprised in a cassette which is easily extractable and exchangeable, for easy repair or for various samplings, having different conduit diameters or configurations and customized magnetic field.

### SUMMARY OF THE INVENTION

It is thus one object of the present invention to provide an extractable nuclear magnetic resonance (NMR) probe cassette (100) for reversibly positioning a probe in an NMR device, comprising a body (120) having a longitudinal axis having an opening at one end of the body, the opening centered on the axis, the body of a non-magnetic material; a conduit (101) extending through the central opening in the body, the conduit for containing a sample and the conduit is of a non-magnetic material; and an RF coil (62) that spirals at least a portion of the central opening; wherein the probe cassette further comprises at least one longitudinal guide (20) along the body's longitudinal axis for reversibly and reproducibly guide the probe cassette in and out of an NMR device.

It is still an object of the present invention to provide the NMR probe cassette as mentioned above wherein the body is of a material selected from the group consisting of alumina, stainless steel, molybdenum, titanium and any combination thereof; and the conduit is of a material selected from the group consisting of alumina, glass, stainless steel, titanium, molybdenum, sapphire, silicon and any combination thereof.

It is still an object of the present invention to provide the NMR probe cassette as mentioned above, wherein the at least one longitudinal guide is selected from the group consisting of tracks, rails, grooves and any combination thereof.

It is still an object of the present invention to provide the NMR probe cassette as mentioned above wherein the body comprises two of the at least one longitudinal guide in a parallel position; the parallel longitudinal guides are secured to either side of the body.

It is still an object of the present invention to provide the NMR probe cassette as mentioned above wherein the conduit is cylindrical, and is adapted to support a sample tube characterized by a diameter of between about 5 mm to about 10 mm.

It is still an object of the present invention to provide the NMR probe cassette as mentioned above further comprising a frequency lock unit positioned within the body and in operative communication with the RF coil and further comprising control electronics in operative communication with the RF coil and the frequency lock unit.

It is still an object of the present invention to provide the NMR probe cassette as mentioned above wherein the conduit is characterized by an open base portion for allowing flow of a sample; the base portion is configured to optionally allow the incorporation of an end portion; the end portion's top defines a floor for insertion of a sample tube.

It is still an object of the present invention to provide the aforementioned NMR probe cassette wherein the base portion is characterized by guides for allowing respective mating with the end portion; the guides define a scale of heights of the end portion.

It is still an object of the present invention to provide the NMR probe cassette as mentioned above wherein the body further includes at least one tube holder located along the body's longitudinal axis and having an opening configured to accommodate and support a sample tube; the tube holder is of a material selected from the group consisting of silicon, glass, alumina and any combination thereof.

It is still an object of the present invention to provide the NMR probe cassette as mentioned above further comprising at least one pin for guiding position of the probe cassette in an NMR device, or further comprising at least one locking means, or both.

It is another object of the present invention to provide a method for reversibly positioning an extractable nuclear magnetic resonance (NMR) probe cassette (100) in an NMR device, comprising the steps of obtaining an NMR probe cassette comprising of a body (120) having a longitudinal axis having an opening at one end of the body, the opening centered on the axis, the body of a non-magnetic material; a conduit (101) extending through the central opening in the body, the conduit for containing a sample and the conduit is of a non-magnetic material; and an RF coil (62) that spirals at least a portion of the central opening; positioning the NMR probe cassette inside an NMR device; wherein the step of obtaining an NMR probe cassette further comprises obtaining the probe cassette comprising at least one longitudinal guide (20) along the body's longitudinal axis; further wherein the step of positioning is done by reversibly and reproducibly guiding the probe cassette in and out of an NMR device by use of the at least one longitudinal guide.

It is another object of the present invention to provide a method for manufacturing an extractable nuclear magnetic resonance (NMR) probe cassette (100) for an NMR device, characterized by steps of constructing a body (120), having a main longitudinal axis, by a non-magnetic material, providing the body with an opening at one end and centering the same on the axis; extending a conduit (101), made of a non-magnetic material, through the central opening in the body, and configuring the conduit for containing a sample; spiral wounding an RF coil (62) at least a portion of the central opening; and, incorporating, in the probe cassette, along the longitudinal axis, at least one elongated guide (20) thereby providing the probe cassette with positioning means for reversibly and reproducibly guiding the probe cassette in and out of an NMR device by use of the at least one longitudinal guide.

It is still an object of the present invention to provide the manufacturing method as mentioned above further comprising the steps of manufacturing the probe cassette wherein the body comprises two of the at least one longitudinal guide in a parallel position; and securing the parallel longitudinal guides to either side of the body.

It is still an object of the present invention to provide the manufacturing method as mentioned above further comprising the steps of manufacturing the probe cassette's conduit in a cylindrical shape, and adapting the probe cassette's conduit to support a sample tube characterized by a diameter of between about 5 mm to about 10 mm.

It is still an object of the present invention to provide the manufacturing method as mentioned above further comprising the steps of positioning in the probe cassette's body a frequency lock unit and configuring the frequency lock unit to be in operative communication with the RF coil; and further positioning in the probe cassette's body control electronics and configuring the control electronics to be in operative communication with the RF coil and the frequency lock unit.

It is still an object of the present invention to provide the manufacturing method as mentioned above further comprising the step of manufacturing the probe cassette's conduit to be characterized by an open base portion for allowing flow of a sample, and further comprising the steps of configuring the base portion to allow the incorporation of an end portion; and optionally incorporating an end portion into the base portion, thereby defining a floor for blocking further insertion of a sample tube

It is still an object of the present invention to provide the aforementioned manufacturing method further comprising the step of configuring the base portion to be have guides for allowing respective mating with the end portion, and further comprising the step of configuring the guides to define a scale of heights of the end portion's position.

It is still an object of the present invention to provide the manufacturing method as mentioned above further comprising the steps of incorporating in the probe cassette's body at least one tube holder located along the body's longitudinal axis and configuring the tube holder to have an opening, thereby accommodating and supporting a sample tube, and further comprising the step of selecting the tube holder's material from the group consisting of silicon, glass, alumina and any combination thereof.

It is still an object of the present invention to provide the manufacturing method as mentioned above further comprising the steps of incorporating in the probe cassette at least one pin for guiding position of the probe cassette in an NMR device, or further comprising the step of incorporating in the probe cassette at least one locking means, or both.

It is also an object of the present invention to provide an open bore NMR device comprising a probe cassette (100) as defined in any of the above.

It is lastly an object of the present invention to provide a method for manufacturing an NMR device, characterized by steps of constructing in the NMR device a bore, and incorporating along the bore's longitudinal axis at least one elongated guide thereby providing the NMR device with positioning guides for reversibly and reproducibly guiding an NMR probe cassette in and out of the NMR device by use of the at least one longitudinal guide.

### BRIEF DESCRIPTION OF THE DRAWINGS

In order to understand the invention and to see how it may be implemented in practice, several embodiments will now be described, by way of non-limiting example only, with reference to the accompanying drawing, in which:

FIG. 1 schematically presents a front view of the probe cassette 100 as disclosed in an embodiment of the present invention.

FIG. 2 schematically presents a top view of the probe cassette of FIG. 1, illustrating the sample introduction section.

FIG. 3 schematically presents a bottom view of the probe cassette of FIG. 1, illustrating the sample outlet section.

FIG. 4 schematically presents a 3D perspective view of the probe cassette of FIG. 1.

FIG. 5 schematically presents a cross-sectional view of the 3D perspective view shown in FIG. 4, illustrating the center of the probe's sample conduit as depicted in lines (a).

FIG. 6 schematically presents an NMR device comprising longitudinal guides for accommodating a probe cassette as disclosed in the present invention.

### DETAILED DESCRIPTION OF THE PREFERRED EMBODIMENTS

The following description is provided, alongside all chapters of the present invention, so that to enable any person skilled in the art to make use of said invention and sets forth the best modes contemplated by the inventor of carrying out this invention. Various modifications, however, will remain apparent to those skilled in the art, since the generic principles of the present invention have been defined specifically to provide an extractable nuclear magnetic resonance (NMR) probe cassette for reversibly positioning a probe in an NMR device, comprising a body having a central opening along its longitudinal axis, the body of a non-magnetic material; a conduit extending through the central opening in the body, the conduit for containing a sample and the conduit is of a non-magnetic material; and an RF coil that spirals at least a portion of the central opening; wherein the probe cassette further comprises at least one longitudinal guide along the body's longitudinal axis for reversibly and reproducibly guide the probe cassette in and out of an NMR device.

The term “about” refers hereinafter to a range of 25% below or above the referred value.

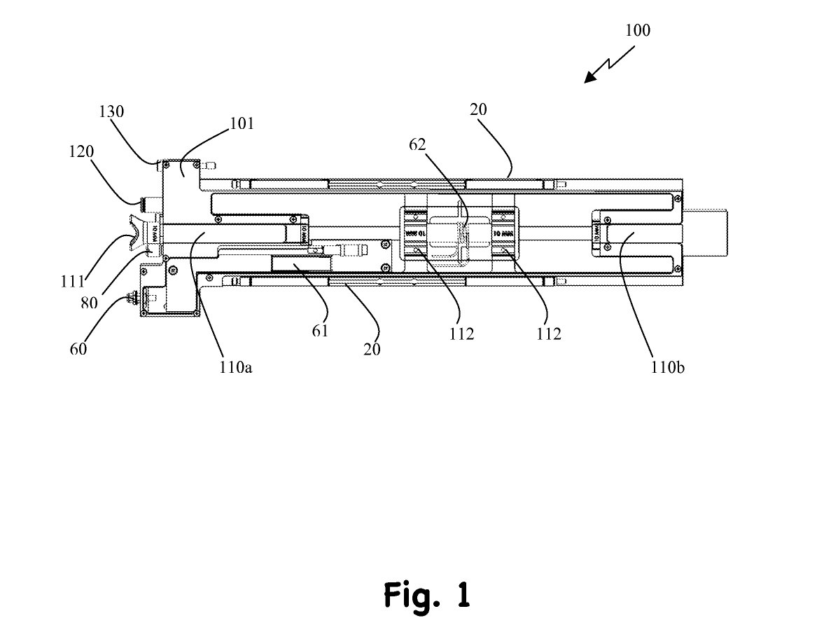

Reference is now made to FIG. 1 schematically presenting a front view of the probe cassette 100. The probe cassette includes a body 101 which comprises a central opening along its longitudinal axis, for the insertion of a sample, in a tube or otherwise. The body is made of a non-magnetic material, and could be made of, in a non-limiting example, alumina, stainless steel, molybdenum, titanium and any combination thereof. Inside the central opening resides a conduit, which in some embodiments may have two distinct sections, a top section 110a and a bottom section 110b. A novel aspect of the present invention is the incorporation of at least one longitudinal guide 20, and preferably two such longitudinal guides 20, along the longitudinal axis of the probe cassette's body. These longitudinal guides are for reversibly, reproducibly and accurately inserting and taking out the probe cassette in and out of an NMR device. The guides could be any mechanical guiding mechanism such as grooves, rails, tracks, etc. The guides could be, for example, in accordance with that detailed in U.S. Pat. No. 7,883,289, incorporated herein as a reference by its entirety. At least part of the central opening is encompassed by an RF coil 62, which spirals around the sample containing area.

An embodiment of the present invention may contain control electronics 61 and these control electronics may be further regulated by RF modulating means 60. The control electronics may also be in operative communication with a frequency lock RF coil 80.

The conduit 110, running across the central opening of the probe cassette, or divided between a top section 110a and a base portion 110b, could be made of any non-magnetic material, and could be made in a non-limiting example of alumina, glass, stainless steel, titanium, molybdenum, sapphire, silicon and any combination thereof. The conduit and any of its segmental parts, could take the preferable shape of a cylinder, but could also assume any other shape (e.g. square, rectangle, polygonal, triangular, oval, etc.). The preferable diameter of the conduit is preferably configured to accommodate a sample tube characterized by a diameter of between about 5 mm and 10 mm, and could also be about 8 mm tube.

In an embodiment of the present invention, as further illustrated in FIG. 1, the conduit at its top end may contain a tube holder 111 in its opening. The tube holder 111 is preferably in the form of a cylinder or the like (although other shapes, e.g. square, rectangle, polygonal, triangular, oval, etc., are also permissible), and could be made from any non-magnetic material, such as in a non-limiting example, silicon, glass, alumina and any combination thereof. At least one other tube holder 112 along the central opening of the probe cassette presents another embodiment of the present invention. The tube holder may have any shape which could clasp any tube having any shape. A preferable embodiment is the incorporation of two such tube holders. The tube holders' function is to accurately locate and guide the sample tube inside the probe cassette.

The conduit's base portion 110b may be in an embodiment configured to allow the incorporation of an end portion. The base portion section may comprise any guides, grooves, rails or the like to allow the sliding of such an end portion. The end portion is mountable to present a mechanical stopper and barrier for the incorporation of a sample tube. That is, the end portion makes up the floor by which the sample tube, inserted through the conduit, will be blocked and held in place. These guides may have a plurality of height adjusters which enable the adjustment of the height of the floor the end portion is creating. Thus, the guides may define a scale of heights which can be determined according to the sample tube used.

The probe cassette in some embodiments may also comprise a heat circulation system 120. The heat circulation system may be, for example, an aperture through which hot or cold air will be able to leave the probe cassette's body and be replaced with air outside the body, which is cooler/warmer. The air may leave in a passive way, or by any ventilation means, including sensor feedback in operable communication with ventilation motors.

The probe cassette may also comprise at least one locking means 130, intended to secure the probe cassette in place inside the NMR device.

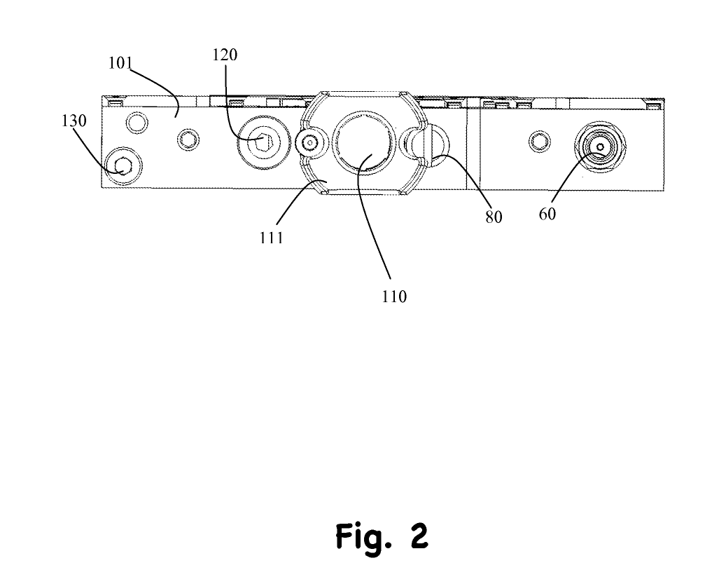

Reference is now made to FIG. 2, illustrating a top view of an embodiment of the probe cassette as disclosed in the present application, and as illustrated in FIG. 1. In the top view is shown the body 101, having the central opening containing the conduit 110, which is intended for inserting a flow-through sample, or a sample tube. Atop the conduit opening, in some embodiments a tube holder 111 may be available for easier insertion of a sample tube. In addition, the top of the probe cassette may also comprise RF modulating means 60 and a frequency lock RF coil 80, as well as at least one aperture of a heat circulation system 120 and at least one locking means 130.

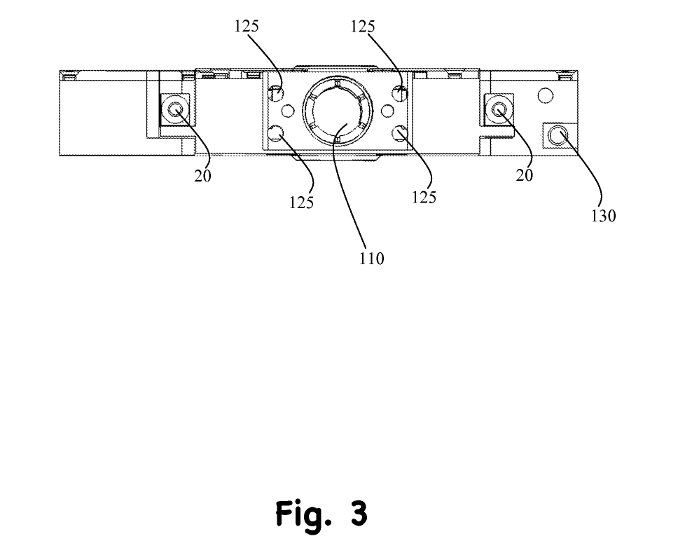

Reference is now made to FIG. 3, illustrating a bottom view of an embodiment of the probe cassette as disclosed in the present invention, and as illustrated in FIG. 1. The bottom view illustrates the probe cassette body 101, having the central opening with conduit 110. An embodiment of the heat circulation system is shown by ventilation holes 125, which assist in circulating hot or cold air in and out of the probe cassette, following the temperature of the sample. The holes 125, may be in addition to other ventilation apertures, such as the ventilation aperture 120 found at the top of the probe cassette. The bottom view also illustrates an embodiment of two rails 20, found in each side of the probe cassette's body, and which are preferably according to the rails depicted in U.S. Pat. No. 7,883,289. The at least one locking means 130 can be seen looking through the bottom view, but is actually found on the top of the probe cassette.

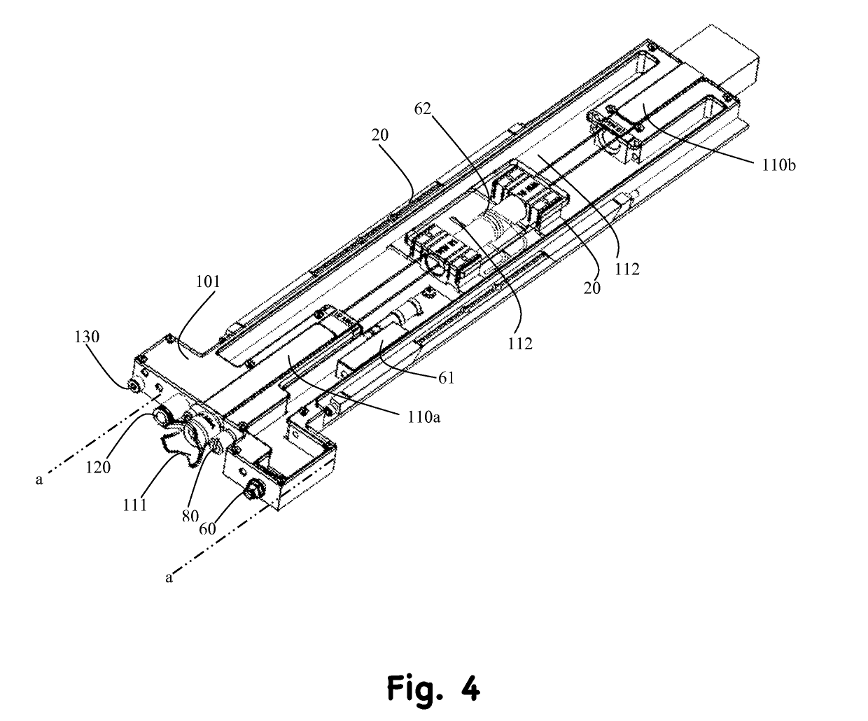

Reference is now made to FIG. 4, illustrating a 3D perspective view of the probe cassette as illustrated in FIG. 1. The illustration shows the main body 101, having a central opening and containing the conduit 110, which under some embodiments may be composed of a top section 110a and a base portion 110b. The sample containing area is at least partially surrounded by RF coils 62, which may be in operative communication with control electronics 61, and may be further regulated by RF modulating means 60. The control electronics may also be in operative communication with a frequency lock RF coil 80. The probe cassette contains at least one longitudinal guides 20, which make the cassette an extractable one. A preferable embodiment of the probe cassette comprises two such longitudinal guides 20, which are preferably incorporated at the sides of the probe cassette's body, and are intended for guiding, inserting and positioning the probe cassette reversibly and accurately into and out of an NMR device. The top of the probe cassette may comprise a tube holder 111, at the opening of the conduit, for supporting a sample tube, and at least one more tube holder 112, preferably two, is located along the longitudinal axis of the probe cassette and is intended for supporting a sample tube. The sample tube may be further supported at its bottom end by an end portion, which may be incorporated at the end portion 110b of the conduit. The top portion of the probe cassette may further comprise at least one heat circulation system 120 and at least one locking means 130.

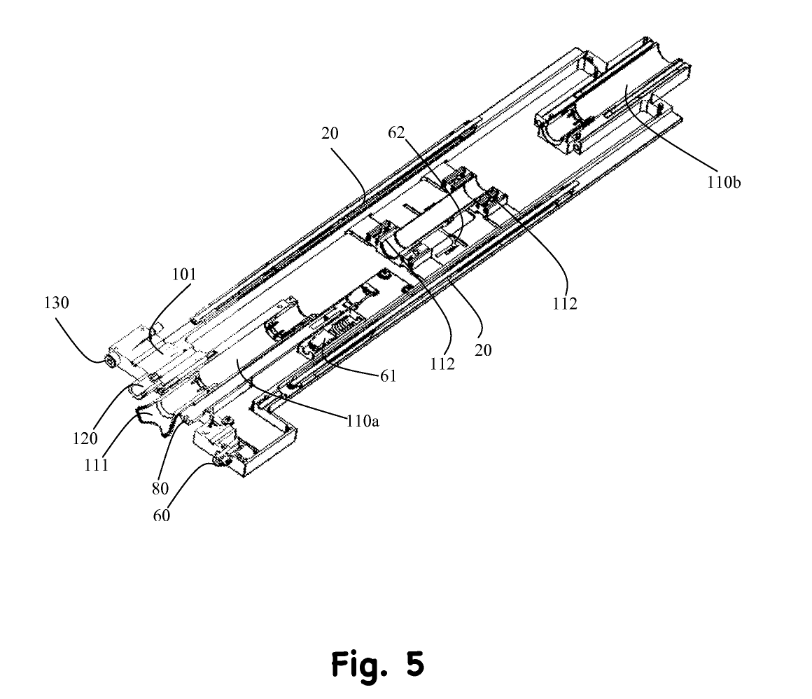

Reference is now made to FIG. 5, illustrating a cross-section taken along the center of the probe cassette, in lines (a), as illustrated in FIG. 4. The probe cassette is in accordance with the one shown in FIG. 4 and similar reference numbers indicate similar features of the probe cassette.

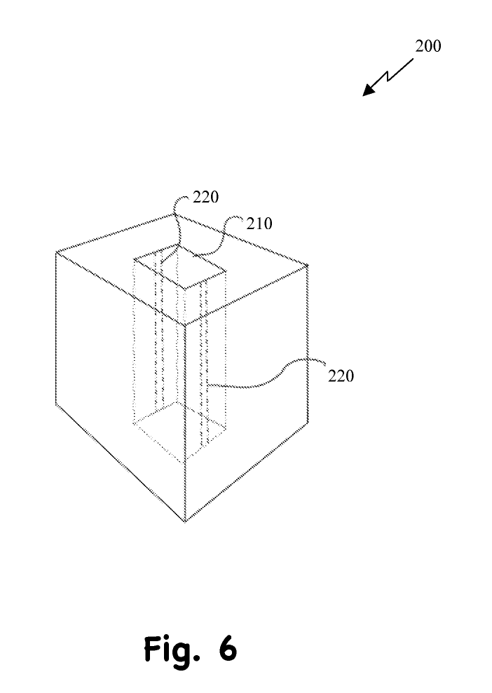

Reference is now made to FIG. 6, illustrating a perspective view of an NMR device 200 manufactured to provide a bore 210. Incorporated in the bore 210 is at least one longitudinal guide 220, and in a preferred embodiment two such longitudinal guides. These longitudinal guides may be, for example and in a non-limiting manner, rails, tracks or any slots, notch, groove, slit or the like. The longitudinal guides are configured to provide the accommodation of the probe cassette 100 as disclosed by the present invention, and are configured to be coordinated with the longitudinal guides provided in the probe cassette.

While the invention is susceptible to various modifications and alternative forms, specific embodiments thereof have been shown by way of example in the drawings and the above detailed description. It should be understood, however, that it is not intended to limit the invention to the particular forms disclosed, but on the contrary, the intention is to cover all modifications, equivalents, and alternatives falling within the spirit and scope of the invention as defined by the appended claims.

1. An extractable nuclear magnetic resonance (NMR) probe cassette (100) for reversibly positioning a probe in an NMR device, comprising:
a. a body (120) having a longitudinal axis having an opening at one end of said body, said opening centered on said axis, said body of a non-magnetic material;
b. a conduit (101) extending through said central opening in said body, said conduit for containing a sample and said conduit is of a non-magnetic material; and
c. an RF coil (62) that spirals at least a portion of said central opening;
wherein said probe cassette further comprises at least one longitudinal guide (20) along said body's longitudinal axis for reversibly and reproducibly guide said probe cassette in and out of an NMR device.

2. The NMR probe cassette according to claim 1, wherein said body is of a material selected from the group consisting of alumina, stainless steel, molybdenum, titanium and any combination thereof; and said conduit is of a material selected from the group consisting of alumina, glass, stainless steel, titanium, molybdenum, sapphire, silicon and any combination thereof.

3. The NMR probe cassette according to claim 1, wherein said at least one longitudinal guide is selected from the group consisting of tracks, rails, grooves and any combination thereof.

4. The NMR probe cassette according to claim 1, wherein said body comprises two of said at least one longitudinal guide in a parallel position; said parallel longitudinal guides are secured to either side of said body.

5. The NMR probe cassette according to claim 1, wherein said conduit is cylindrical, and is adapted to support a sample tube characterized by a diameter of between about 5 mm to about 10 mm.

6. The NMR probe cassette according to claim 1, further comprising a frequency lock unit positioned within said body and in operative communication with said RF coil and further comprising control electronics in operative communication with said RF coil and said frequency lock unit.

7. The NMR probe cassette according to claim 1, wherein said conduit is characterized by an open base portion for allowing flow of a sample; said base portion is configured to optionally allow the incorporation of an end portion; said end portion's top defines a floor for insertion of a sample tube.

8. The NMR probe cassette according to claim 7, wherein said base portion is characterized by guides for allowing respective mating with said end portion; said guides define a scale of heights of said end portion.

9. The NMR probe cassette according to claim 1, wherein said body further includes at least one tube holder located along said body's longitudinal axis and having an opening configured to accommodate and support a sample tube; said tube holder is of a material selected from the group consisting of silicon, glass, alumina and any combination thereof.

10. The NMR probe cassette according to claim 1, further comprising at least one pin for guiding position of said probe cassette in an NMR device, or further comprising at least one locking means, or both.

11. A method for analyzing a sample in an extractable nuclear magnetic resonance (NMR) probe cassette (100) in an NMR device, comprising the steps of:
a. obtaining an NMR probe cassette comprising of:
i. a body (120) having a longitudinal axis having an opening at one end of said body, said opening centered on said axis, said body of a non-magnetic material;
ii. a conduit (101) extending through said central opening in said body, said conduit for containing a sample and said conduit is of a non-magnetic material; and
iii. an RF coil (62) that spirals at least a portion of said central opening;
b. positioning said NMR probe cassette inside an NMR device;
wherein said step of obtaining an NMR probe cassette further comprises obtaining said probe cassette comprising at least one longitudinal guide (20) along said body's longitudinal axis;
further wherein said step of positioning is done by reversibly and reproducibly guiding said probe cassette in and out of an NMR device by use of said at least one longitudinal guide.

12. A method for manufacturing an extractable nuclear magnetic resonance (NMR) probe cassette (100) for an NMR device, characterized by steps of constructing a body (120), having a main longitudinal axis, by a non-magnetic material, providing said body with an opening at one end and centering the same on said axis; extending a conduit (101), made of a non-magnetic material, through said central opening in said body, and configuring said conduit for containing a sample; spiral wounding an RF coil (62) at least a portion of said central opening; and, incorporating, in said probe cassette, along said longitudinal axis, at least one elongated guide (20) thereby providing said probe cassette with positioning means for reversibly and reproducibly guiding said probe cassette in and out of an NMR device by use of said at least one longitudinal guide.

13. The method according to claim 12, further comprising the steps of manufacturing said probe cassette wherein said body comprises two of said at least one longitudinal guide in a parallel position; and securing said parallel longitudinal guides to either side of said body.

14. The method according to claim 12, further comprising the steps of manufacturing said probe cassette's conduit in a cylindrical shape, and adapting said probe cassette's conduit to support a sample tube characterized by a diameter of between about 5 mm to about 10 mm.

15. The method according to claim 12, further comprising the steps of positioning in said probe cassette's body a frequency lock unit and configuring said frequency lock unit to be in operative communication with said RF coil; and further positioning in said probe cassette's body control electronics and configuring said control electronics to be in operative communication with said RF coil and said frequency lock unit.

16. The method according to claim 12, further comprising the step of manufacturing said probe cassette's conduit to be characterized by an open base portion for allowing flow of a sample, and further comprising the steps of configuring said base portion to allow the incorporation of an end portion; and optionally incorporating an end portion into said base portion, thereby defining a floor for blocking further insertion of a sample tube.

17. The method according to claim 18, further comprising the step of configuring said base portion to be have guides for allowing respective mating with said end portion, and further comprising the step of configuring said guides to define a scale of heights of said end portion's position.

18. The method according to claim 12, further comprising the steps of incorporating in said probe cassette's body at least one tube holder located along said body's longitudinal axis and configuring said tube holder to have an opening, thereby accommodating and supporting a sample tube, and further comprising the step of selecting said tube holder's material from the group consisting of silicon, glass, alumina and any combination thereof.

19. The method according to claim 12, further comprising the steps of incorporating in said probe cassette at least one pin for guiding position of said probe cassette in an NMR device, or further comprising the step of incorporating in said probe cassette at least one locking means, or both.

20. An open bore NMR device (200) having an NMR probe cassette (100) according to claim 1.
